(19) United States
(12) Patent Application Publication
(10) Pub. No.: US 2024/0333261 A1
(43) Pub. Date: Oct. 3, 2024

(54) MULTIPLEXER

(71) Applicant: Murata Manufacturing Co., Ltd., Nagaokakyo-shi (JP)

(72) Inventor: Akira NOGUCHI, Nagaokakyo-shi (JP)

(21) Appl. No.: 18/603,329

(22) Filed: Mar. 13, 2024

(30) Foreign Application Priority Data
Apr. 3, 2023 (JP) 2023-060095

(51) Int. Cl. H03H 9/64; H03H 9/72; H04B 1/00

(52) U.S. Cl. CPC H03H 9/6483; H03H 9/725; H04B 1/0057

(57) ABSTRACT

A multiplexer includes first, second, and third filter circuits, and an additional circuit, at least a portion of which is connected in parallel to each of the first, second, and third filter circuits. The additional circuit includes first, second, and third IDTs and two reflectors. The first IDT is connected to a path connecting a first terminal and the first filter circuit or a path extending through an inside of the first filter circuit. The third IDT is connected to a path connecting a third terminal and the third filter circuit or a path extending through an inside of the third filter circuit. The second IDT is connected to a path connecting the first filter circuit and a common terminal, a path connecting the third filter circuit and the common terminal, or a path connecting the second filter circuit and the common terminal.

### CROSS REFERENCE TO RELATED APPLICATIONS

This application claims the benefit of priority to Japanese Patent Application No. 2023-060095 filed on Apr. 3, 2023. The entire contents of this application are hereby incorporated herein by reference.

### BACKGROUND OF THE INVENTION

### 1. Field of the Invention

The present invention relates to multiplexers each including three or more filter circuits.

### 2. Description of the Related Art

In recent years, multiband systems are being used to improve the data transmission speeds of mobile phones. At that time, transmission and reception of a plurality of frequency bands may be performed. Thus, in a front-end circuit of the mobile phone, a plurality of filter circuits that allow radio frequency signals of different frequency bands to pass are installed. In this case, it is desirable that the foregoing plurality of filter circuits secure sufficient attenuation in attenuation bands outside the pass bands.

In FIG. 10 of International Publication No. 2020/031783, a multiplexer including two transmission filter circuits, two reception filter circuits, and an additional circuit connected in parallel to one of these two transmission circuits is disclosed.

For example, in order to secure attenuation in each of the attenuation bands of the plurality of filter circuits, it is conceivable to connect an additional circuit to each of the plurality of filter circuits. However, if a plurality of additional circuits are connected in such a manner as to correspond to a plurality of filter circuits, there will be an issue of an increase in the total number of reflectors or IDTs (InterDigital Transducer) included in the plurality of additional circuits.

### SUMMARY OF THE INVENTION

Example embodiments of the present invention provide multiplexers that are each able to reduce the total number of reflectors or IDTs included in additional circuit(s).

A multiplexer according to an example embodiment of the present invention includes three or more filter circuits with pass bands that are different from one another, a common terminal, a first terminal, a second terminal, and a third terminal, a first filter circuit in a first path connecting the first terminal and the common terminal, a second filter circuit in a second path connecting the second terminal and the common terminal, a third filter circuit in a third path connecting the third terminal and the common terminal, and an additional circuit, at least a portion of which is connected in parallel to each of the first filter circuit and the third filter circuit. The additional circuit includes three or more IDTs aligned along a first direction and two reflectors on both outer sides of the three or more IDTs in the first direction. Of the three or more IDTs, a first IDT is connected to a path connecting the first terminal and the first filter circuit or a path extending through an inside of the first filter circuit, the path connecting the first terminal and the first filter circuit and the path extending through the inside of the first filter circuit each being a portion of the first path. Of the three or more IDTs, a third IDT is connected to a path connecting the third terminal and the third filter circuit or a path extending through an inside of the third filter circuit, the path connecting the third terminal and the third filter circuit and the path extending through the inside of the third filter circuit each being a portion of the first path. Of the three or more IDTs, a second IDT is connected to a first common terminal side path that is a portion of the first path and connects the first filter circuit and the common terminal, a third common terminal side path that is a portion of the third path and connects the third filter circuit and the common terminal, or a second common terminal side path that is a portion of the second path and connects the second filter circuit and the common terminal.

According to example embodiments of the present invention, it becomes possible to provide multiplexers that are each able to reduce the total number of reflectors or IDTs included in additional circuit(s).

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram of a multiplexer of a comparative example 1.

FIG. 2 is a circuit configuration diagram of a multiplexer according to an example embodiment of the present invention.

FIG. 3 is a diagram illustrating bandpass characteristics of respective filter circuits included in a multiplexer according to an example embodiment of the present invention.

FIG. 4 is a schematic diagram illustrating an IDT group and the like of an additional circuit included in a multiplexer according to an example embodiment of the present invention.

FIG. 5 is a circuit configuration diagram of a multiplexer of a comparative example 2.

FIG. 6 is a diagram illustrating electrode parameters of an IDT group of an additional circuit included in a multiplexer of a working example.

FIG. 7 is a diagram illustrating a bandpass characteristic of a third filter circuit included in a multiplexer according to an example embodiment of the present invention.

FIG. 8 is a diagram illustrating a bandpass characteristic of a first filter circuit included in a multiplexer according to an example embodiment of the present invention.

FIG. 9 is a circuit configuration diagram of a multiplexer according to a modified example 1 of an example embodiment of the present invention.

FIG. 10 is a circuit configuration diagram of a multiplexer according to a modified example 2 of an example embodiment of the present invention.

### DETAILED DESCRIPTION OF THE EXAMPLE EMBODIMENTS

Details leading to example embodiments of the present invention will be described with reference to a comparative example 1.

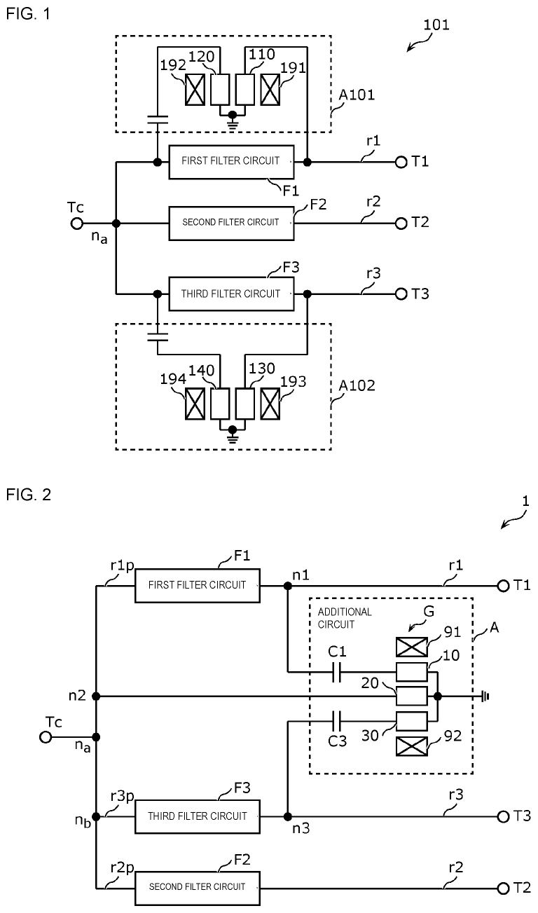

FIG. 1 is a circuit configuration diagram of a multiplexer 101 of the comparative example 1.

The multiplexer 101 of the comparative example 1 includes a first filter circuit F1, a second filter circuit F2, a third filter circuit F3, and two additional circuits A101 and A102. Pass bands of the first filter circuit F1, the second filter circuit F2, and the third filter circuit F3 are different from each other.

The additional circuit A101, which is one of the two additional circuits, includes two IDTs 110 and 120 and two reflectors 191 and 192. Further, the additional circuit A102, which is the other of the two additional circuits, includes two IDTs 130 and 140 and two reflectors 193 and 194. The additional circuit A101, which is the one of the two additional circuits, is connected in parallel to the first filter circuit F1, and the additional circuit A102, which is the other of the two additional circuits, is connected in parallel to the third filter circuit F3.

According to the configuration of the comparative example 1, it becomes possible to ensure attenuation in an attenuation band outside the pass band of the first filter circuit F1 and further, it becomes possible to ensure attenuation in an attenuation band outside the pass band of the third filter circuit F3. However, in the comparative example 1, two additional circuits are required, and the total number of the reflectors, the IDTs, and the like of the additional circuits A101 and A102 is increased. In this example, four reflectors and four IDTs are required, and this leads to an issue of an increase in size of the multiplexer 101.

In order to reduce the total number of reflectors or IDTs included in additional circuit(s), multiplexers according to example embodiments of the present invention each have the configuration described below.

Hereinafter, example embodiments of the present invention will be described in detail using diagrams and charts. The working examples, which will be described below, each illustrate a comprehensive or specific example. Numeric values, shapes, materials, elements, arrangements and connection configurations of the elements, and the like illustrated in the following working examples are mere examples, and not intended to limit the scope of the present invention. Of elements in the following working examples, the elements that are not described in an independent claim will be described as optional elements. Further, dimensions or ratios of dimensions of elements illustrated in the drawings are not necessarily precise and do not limit example embodiments of the present invention.

### EXAMPLE EMBODIMENTS

### Configuration of Multiplexer

The configuration of a multiplexer according to an example embodiment of the present invention is described with reference to FIG. 2 to FIG. 4.

FIG. 2 is a circuit configuration diagram of a multiplexer 1 according to the present example embodiment.

The multiplexer 1 according to the present example embodiment includes three or more filter circuits whose pass bands are different from each other and an additional circuit.

The multiplexer 1 illustrated in FIG. 2 includes a first filter circuit F1, a second filter circuit F2, a third filter circuit F3, and a single additional circuit A. Further, the multiplexer 1 includes a common terminal Tc, a first terminal T1, a second terminal T2, and a third terminal T3.

The common terminal Tc is a common terminal of the first filter circuit F1, the second filter circuit F2, and the third filter circuit F3 and is connected to an antenna. Extended lines of the first filter circuit F1, the second filter circuit F2, and the third filter circuit F3, are bundled together at a node na and connected to the common terminal Tc.

The first filter circuit F1 is provided in a first path r1 that connects the first terminal T1 and the common terminal Tc. For example, the first filter circuit F1 filters a transmission wave input to the first terminal T1 using a first pass band and outputs a filtered wave to the common terminal Tc.

The third filter circuit F3 is provided in a third path r3 that connects the third terminal T3 and the common terminal Tc. For example, the third filter circuit F3 filters a transmission wave input to the third terminal T3 using a third pass band and outputs a filtered wave to the common terminal Tc.

The second filter circuit F2 is provided in a second path r2 that connects the second terminal T2 and the common terminal Tc. For example, the second filter circuit F2 filters a reception wave input to the common terminal Tc using a second pass band and outputs a filtered wave to the second terminal T2.

Each of the filter circuits F1, F2, and F3 includes a plurality of series arm resonators and a plurality of parallel arm resonators. The plurality of series arm resonators are connected in series to each other, and the plurality of parallel arm resonators are each arranged in a path between a node between adjacent series arm resonators and a reference terminal (ground). Because of the foregoing connection configuration of the series arm resonators and the parallel arm resonators, each of the filter circuit F1, F2, and F3 defines, for example, a ladder band pass filter. A circuit element such as, for example, an inductor or the like may be inserted between the parallel arm resonator and the ground. Further, the second filter circuit F2 may include a longitudinally coupled resonant circuit or may be a LC filter, for example.

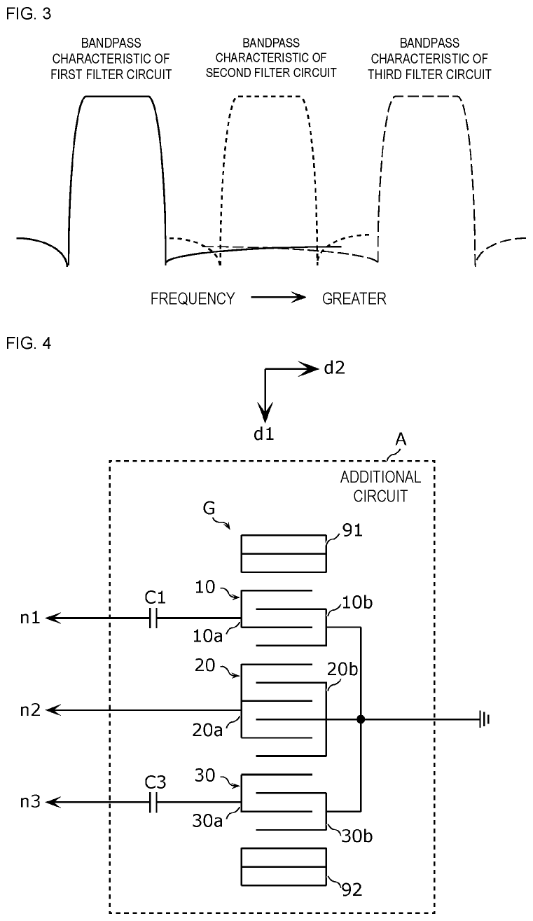

FIG. 3 is a diagram illustrating bandpass characteristics of respective ones of the plurality of the filter circuits F1, F2, and F3 included in the multiplexer 1.

For example, the first filter circuit F1 is a circuit for a transmission filter whose pass band (Band 28Tx) is from about 703 MHz to about 748 MHz. The third filter circuit F3 is a circuit for a transmission filter whose pass band (Band 20Tx) is from about 832 MHz to about 862 MHZ. The second filter circuit F2 is a circuit for a reception filter whose pass band (Band 20Rx+Band 28Rx) is from about 758 MHz to about 821 MHZ. The second filter circuit F2 is used as a shared reception filter that corresponds to the two transmission filters.

In this example, the pass band of the second filter circuit F2 is higher than the pass band of the first filter circuit F1 and lower than the pass band of the third filter circuit F3. Further, an attenuation band of the first filter circuit F1, an attenuation band of the third filter circuit F3, and the pass band of the second filter circuit F2 overlap at least partially with each other. Further, the attenuation band of the first filter circuit F1 on the high frequency side, which is higher than the pass band of the first filter circuit F1, partially overlaps the pass band of the third filter circuit F3. The attenuation band of the third filter circuit F3 on the low frequency side, which is lower than the pass band of the third filter circuit F3, partially overlaps the pass band of the first filter circuit F1.

The additional circuit A illustrated in FIG. 2 is a cancel circuit that includes an offset component with the inverted phase and the same or substantially the same amplitude of that of a filter circuit to ensure attenuation outside the pass band of the filter circuit. As illustrated in FIG. 2, the additional circuit A is connected in parallel to each of the first filter circuit F1 and the third filter circuit F3. In this multiplexer 1, in order to reduce the total number of reflectors or IDTs included in the additional circuit A, the single additional circuit A is shared by the two filter circuits F1 and F3.

The additional circuit A includes an IDT group G including three IDTs and two reflectors provided on both outer sides of these three IDTs. The IDT group G is, for example, a longitudinally coupled acoustic wave resonator. The three IDTs include a first IDT 10, a second IDT 20, and a third IDT 30. In the present example embodiment, the number of the IDTs included in the additional circuit A is equal to the number (three) of the plurality of filter circuits included in the multiplexer 1.

The first IDT 10 is connected to a path connecting the first terminal T1 and the first filter circuit F1, which is a portion of the first path r1. In this example, the first IDT 10 is connected to a node n1 in the path connecting the first terminal T1 and the first filter circuit F1 via a reactance element C1. The first IDT 10 may be connected to a path extending through the inside of the first filter circuit F1, which is a portion of the first path r1. The phrase “being connected to a path extending through the inside” described above is defined to mean that the first IDT 10 is connected between mutually adjacent two series arm resonators in the inside of the first filter circuit F1.

The third IDT 30 is connected to a path connecting the third terminal T3 and the third filter circuit F3, which is a portion of the third path r3. In the present example embodiment, the third IDT 30 is connected to a node n3 in the path connecting the third terminal T3 and the third filter circuit F3 via a reactance element C3. The third IDT 30 may be connected to a path extending through the inside of the third filter circuit F3, which is a portion of the third path r3. The phrase “being connected to a path extending through the inside” described above is defined to mean that the third IDT 30 is connected between mutually adjacent two series arm resonators in the inside of the third filter circuit F3.

The second IDT 20 is connected to a first common terminal side path r1p that is a portion of the first path r1 and connects the first filter circuit F1 and the common terminal Tc, a third common terminal side path r3p that is a portion of the third path r3 and connects the third filter circuit F3 and the common terminal Tc, or a second common terminal side path r2p that is a portion of the second path r2 and connects the second filter circuit F2 and the common terminal Tc. The first common terminal side path r1p, the third common terminal side path r3p, and the second common terminal side path r2p are at the same potential.

In the present example embodiment, the second IDT 20 is connected to a node n2 in the path connecting the first filter circuit F1 and the common terminal Tc. The second IDT 20 may be connected to a node na or may be connected to a node nb in a path connecting the second filter circuit F2 to the common terminal Tc and the third filter circuit F3 to the common terminal Tc. Further, the second IDT 20 may alternatively be connected to the node n2 via another reactance element (illustration thereof is omitted).

FIG. 4 is a schematic diagram illustrating the IDT group G and the like of the additional circuit A included in the multiplexer 1.

FIG. 4 shows a diagram of the IDT group G seen from the direction vertical to a piezoelectric substrate on which the IDTs and the reflectors are provided. A first direction d1 illustrated in FIG. 4 is a direction along a principal surface of the piezoelectric substrate, along which acoustic waves of IDTs propagate. A second direction d2 is a direction along the principal surface of the piezoelectric substrate and is orthogonal or substantially orthogonal to the first direction d1.

The IDT group G includes the three IDTs 10, 20, and 30 that line up along the first direction d1 and two reflectors 91 and 92 provided on both outer sides of the three IDTs 10 to 30 in the first direction d1.

The two reflectors include a first reflector 91 and a second reflector 92. Each of the two reflector 91 and 92 includes a plurality of reflection electrode fingers extending in the second direction d2 and a busbar electrode that connects end portions of respective ones of the plurality of reflection electrode fingers. The plurality of reflection electrode fingers are aligned along the first direction d1 with a predetermined pitch.

In the first direction d1, the three IDTs are arranged in the order of the first IDT 10, the second IDT 20, and the third IDT 30. That is to say, the second IDT 20 is arranged between the first IDT 10 and the third IDT 30 in the first direction d1.

Each of the three IDTs 10 to 30 includes a pair of comb-shaped electrodes arranged opposite each other. The pair of comb-shaped electrodes include one comb-shaped electrode and the other comb-shaped electrode of the pair of comb-shaped electrodes. Specifically, the pair of comb-shaped electrodes of the IDT 10 includes one comb-shaped electrode 10a and the other comb-shaped electrode 10b. The pair of comb-shaped electrodes of the IDT 20 include one comb-shaped electrode 20a and the other comb-shaped electrode 20b. The pair of comb-shaped electrodes of the IDT 30 is made up of one comb-shaped electrode 30a and the other comb-shaped electrode 30b.

The one comb-shaped electrode includes a plurality of electrode fingers extending in the second direction d2, which crosses the first direction d1, and a busbar electrode that connects end portions of respective ones of the plurality of electrode fingers. The other comb-shaped electrode includes a plurality of electrode fingers extending in the second direction d2 and a busbar electrode that connects end portions of respective ones of the plurality of electrode fingers. These electrode fingers are aligned along the first direction d1 with a predetermined pitch. These electrode fingers partially overlap with each other when these electrode fingers are seen from the first direction d1.

The busbar electrodes of the one comb-shaped electrodes 10a, 20a, and 30a are arranged on the negative side in the second direction d2 when these busbar electrodes are seen from intersecting areas where parts of the electrode fingers overlap. The busbar electrodes of the other comb-shaped electrodes 10b, 20b, and 30b are arranged on the positive side in the second direction d2 when these busbar electrodes are seen from the intersecting areas described above. That is to say, the one comb-shaped electrodes 10a, 20a, and 30a and the other comb-shaped electrodes 10b, 20b, and 30b are arranged so as to be opposite to each other and directed in opposite directions when the intersecting area is used as a reference.

Each of the other comb-shaped electrodes 10b, 20b, and 30b of the first IDT 10, the second IDT 20, and the third IDT 30 is connected to the ground via an extended wiring line connected to each of the other comb-shaped electrodes 10b, 20b, and 30b.

Each of the one comb-shaped electrodes 10a, 20a, and 30a of the first IDT 10, the second IDT 20, and the third IDT 30 is connected to a signal line via an extended wiring line connected to each of the one comb-shaped electrodes 10a, 20a, and 30a. Specifically, the one comb-shaped electrode 10a of the first IDT 10 is connected to the node n1 via the extended wiring line and the reactance element C1. The one comb-shaped electrode 30a of the third IDT 30 is connected to the node n3 via the extended wiring line and the reactance element C3. The one comb-shaped electrode 20a of the second IDT 20 is connected to the node n2 via the extended wiring line.

In a predetermined band of the attenuation band outside the pass band of the first filter circuit F1, the additional circuit A outputs, to the node n2, an offset component with the inverted phase and the same or substantially the same amplitude of that of the first filter circuit F1. Because of this, it becomes possible to ensure attenuation in the attenuation band of the first filter circuit F1. Further, in a predetermined band of the attenuation band outside the pass band of the third filter circuit F3, the additional circuit A outputs, to the node n2, an offset component with the inverted phase and the same or substantially the same amplitude of that of the third filter circuit F3. Because of this, it becomes possible to ensure attenuation in the attenuation band of the third filter circuit F3.

In the additional circuit A of the present example embodiment, the first IDT 10 is connected to the path connecting the first terminal T1 and the first filter circuit F1, the third IDT 30 is connected to the path connecting the third terminal T3 and the third filter circuit F3, and the second IDT 20 is connected to the first common terminal side path r1p, the third common terminal side path r3p, or the second common terminal side path r2p.

According to the multiplexer 1 having the above-described configuration, the single additional circuit A can provide functions equivalent to those of two additional circuits to be connected to the two filter circuits F1 and F3. Because of this, it becomes possible to reduce the total number of the reflectors or the IDTs included in the additional circuit A. In the present example embodiment, the additional circuit A includes two reflectors and three IDTs, and compared with the comparative example 2, it becomes possible to reduce the total number of the reflectors and the IDTs.

### Attenuation in Attenuation Band Outside Pass Band of Filter Circuit

Attenuation in the attenuation band outside the pass band of the filter circuit will be described. Here, the description will be provided by comparing a comparative example 2 to a working example of an example embodiment.

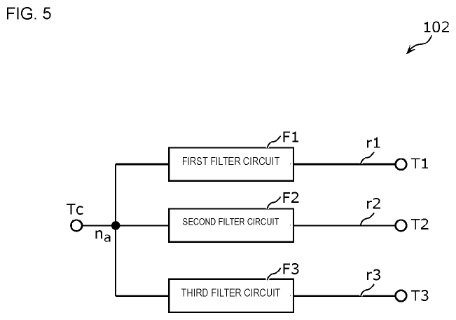

FIG. 5 is a circuit configuration diagram of a multiplexer 102 of the comparative example 2.

As illustrated in FIG. 5, the multiplexer 102 of the comparative example 2 does not include any additional circuit and includes only three filter circuits F1, F2, and F3.

The multiplexer 1 of the working example includes the three filter circuits F1, F2, and F3 and the additional circuit A.

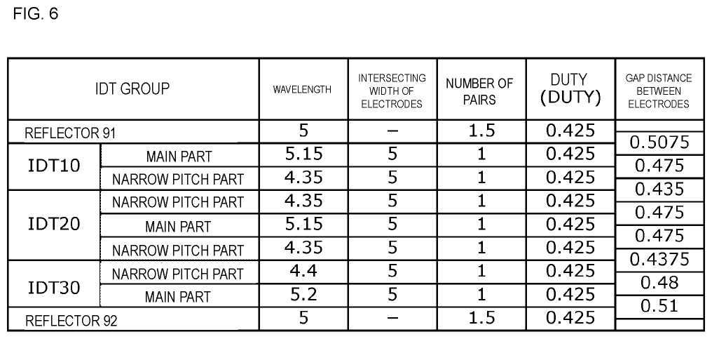

FIG. 6 is a diagram illustrating electrode parameters of the IDT group G of the additional circuit A included in the multiplexer 1 of the working example.

FIG. 6 indicates electrode parameters of each of the three IDTs 10, 20, and 30 and the two reflectors 91 and 92 of the IDT group. In FIG. 6, the wavelength, the intersecting width of the IDT electrodes, the number of pairs, the duty, and the gap between the electrodes of the IDT or the reflector are indicated. With regard to each of the IDTs 10, 20, and 30, the electrode parameters of a main portion that defines and functions as the main portion of each IDT and a narrow pitch portion or narrow pitch portions where the pitch of electrode finger arrangement is narrower than that of the main portion are indicated.

With the conditions described above, attenuation in the attenuation bands of the filter circuits of the multiplexers of the comparative example 2 and the working example are now described.

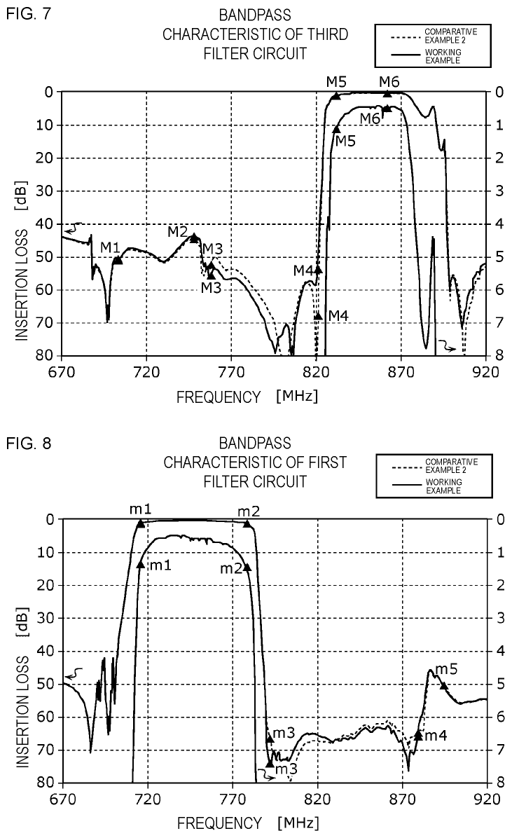

FIG. 7 is a diagram illustrating the bandpass characteristic of the third filter circuit F3. FIG. 7 illustrates the bandpass characteristic of the third filter circuit F3 that includes the additional circuit A.

As illustrated in FIG. 7, of the attenuation band of the third filter circuit F3, in the band between M3-M4 illustrated in FIG. 7, the working example has greater attenuation (the insertion loss illustrated in FIG. 7) than the comparative example 2. Specifically, the worst value of the attenuation between M3-M4 is smaller in the working example than in the comparative example 2. As described above, by connecting the foregoing additional circuit A to the third filter circuit F3, it becomes possible to ensure attenuation in the attenuation band of the third filter circuit F3.

FIG. 8 is a diagram illustrating the bandpass characteristic of the first filter circuit F1. FIG. 8 illustrates the bandpass characteristic of the first filter circuit F1 that includes the additional circuit A.

As illustrated in FIG. 8, of the attenuation band of the first filter circuit F1, in the band between m3-m4 illustrated in FIG. 8, the working example has greater attenuation than the comparative example 2. Specifically, the worst value of the attenuation between m3-m4 is smaller in the working example than in the comparative example 2. As described above, by connecting the foregoing additional circuit A to the first filter circuit F1, it becomes possible to ensure attenuation in the attenuation band of the first filter circuit F1.

### Modified Example 1 of Example Embodiment

The configuration of a multiplexer 1A according to a modified example 1 of an example embodiment of the present invention is described. In the modified example 1, there is described an example in which an additional circuit Aa includes five IDTs.

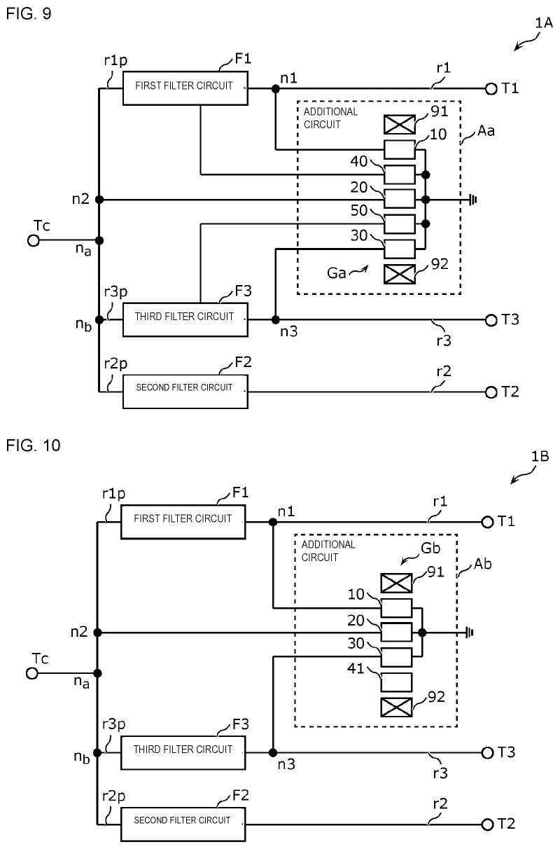

FIG. 9 is a circuit configuration diagram of the multiplexer 1A according to the modified example 1 of the example embodiment.

The multiplexer 1A of the modified example 1 includes the first filter circuit F1, the second filter circuit F2, the third filter circuit F3, and the single additional circuit Aa. Further, the multiplexer 1A includes the common terminal Tc, the first terminal T1, the second terminal T2, and the third terminal T3.

The additional circuit Aa includes an IDT group Ga including five IDTs and two reflectors provided on both outer sides of these five IDTs. The IDT group Ga is, for example, a longitudinally coupled acoustic wave resonator. The five IDTs include the first IDT 10, the second IDT 20, the third IDT 30, a fourth IDT 40, and a fifth IDT 50. The five IDTs are arranged in the order of the first IDT 10, the fourth IDT 40, the second IDT 20, the fifth IDT 50, and the third IDT 30 in the first direction d1.

The first IDT 10 is connected to a path connecting the first terminal T1 and the first filter circuit F1, which is a portion of the first path r1. In the present example, the first IDT 10 is connected to the node n1 in the path connecting the first terminal T1 and the first filter circuit F1.

The fourth IDT 40 connected to a path extending through the inside of the first filter circuit F1, which is a portion of the first path r1.

The third IDT 30 is connected to a path connecting the third terminal T3 and the third filter circuit F3, which is a portion of the third path r3. In the present example, the third IDT 30 is connected to the node n3 in the path connecting the third terminal T3 and the third filter circuit F3.

The fifth IDT 50 is connected to a path extending through the inside of the third filter circuit F3, which is a portion of the third path r3.

The second IDT 20 is connected to the first common terminal side path r1p that is a portion of the first path r1, the third common terminal side path r3p that is a portion of the third path r3, or the second common terminal side path r2p that is a portion of the second path r2. In the present example, the second IDT 20 is connected to the node n2. The second IDT 20 may alternatively be connected to the node na or may alternatively be connected to the node nb.

According to the multiplexer 1A of the present modified example 1, the single additional circuit Aa can provide the functions equivalent to those of two additional circuits to be connected to the two filter circuits F1 and F3. Because of this, it becomes possible to reduce the total number of the reflectors included in the additional circuit Aa. In the present example, the additional circuit Aa includes two reflectors and five IDTs, and thus the total number of the reflectors can be reduced compared with the comparative example 2.

### Modified Example 2 of Example Embodiment

The configuration of a multiplexer 1B according to a modified example 2 of an example embodiment of the present invention is described. In the modified example 2, an example is described in which an additional circuit Ab includes four IDTs.

FIG. 10 is a circuit configuration diagram of the multiplexer 1B according to the modified example 2.

The multiplexer 1B of the modified example 2 includes the first filter circuit F1, the second filter circuit F2, the third filter circuit F3, and the single additional circuit Ab. Further, the multiplexer 1B includes the common terminal Tc, the first terminal T1, the second terminal T2, and the third terminal T3.

The additional circuit Ab includes an IDT group Gb including four IDTs and two reflectors provided on both outer sides of these four IDTs. The IDT group Gb is, for example, a longitudinally coupled acoustic wave resonator. The four IDTs include the first IDT 10, the second IDT 20, the third IDT 30, and a fourth IDT 41. The four IDTs are arranged in the order of the first IDT 10, the second IDT 20, the third IDT 30, and the fourth IDT 41 in the first direction d1.

The first IDT 10 is connected to a path connecting the first terminal T1 and the first filter circuit F1, which is a portion of the first path r1. In the present example, the first IDT 10 is connected to the node n1 in the path connecting the first terminal T1 and the first filter circuit F1.

The third IDT 30 is connected to a path connecting the third terminal T3 and the third filter circuit F3, which is a portion of the third path r3. In the present example, the third IDT 30 is connected to the node n3 in the path connecting the third terminal T3 and the third filter circuit F3.

The second IDT 20 is connected to the first common terminal side path r1p that is a portion of the first path r1, the third common terminal side path r3p that is a portion of the third path r3, or the second common terminal side path r2p that is a portion of the second path r2. In the present example, the second IDT 20 is connected to the node n2. Alternatively, the second IDT 20 may be connected to the node na or may be connected to the node nb.

The fourth IDT 41 is not connected to any of the paths and defines and functions as a floating electrode.

According to the multiplexer 1B of the modified example 2, the single additional circuit Ab can provide the functions equivalent to those of two additional circuits to be connected to the two filter circuits F1 and F3. Because of this, it becomes possible to reduce the total number of the reflectors or the IDTs included in the additional circuit Ab. In the present example, the additional circuit Ab includes two reflectors and four IDTs, and thus the total number of the reflectors can be reduced compared with the comparative example 2.

Example configurations of multiplexers according to example embodiments of the present invention are described below.

### Example 1

The multiplexer 1 according to an example embodiment of the present invention includes three or more filter circuits whose pass bands are different from each other. The multiplexer 1 includes the common terminal Tc, the first terminal T1, the second terminal T2, and the third terminal T3, the first filter circuit F1 provided in the first path r1 connecting the first terminal T1 and the common terminal Tc, the second filter circuit F2 provided in the second path r2 connecting the second terminal T2 and the common terminal Tc, the third filter circuit F3 provided in the third path r3 connecting the third terminal T3 and the common terminal Tc, and the additional circuit A, at least a portion of which is connected in parallel to each of the first filter circuit F1 and the third filter circuit F3. The additional circuit A includes three or more IDTs aligned along the first direction d1 and two reflectors 91 and 92 provided on both outer sides of the three or more IDTs in the first direction d1. Of the three or more IDTs, the first IDT 10 is connected to the path connecting the first terminal T1 and the first filter circuit F1 or the path extending through the inside of the first filter circuit F1, which is a portion of the first path r1. Of the three or more IDTs, the third IDT 30 is connected to the path connecting the third terminal T3 and the third filter circuit F3 or the path extending through the inside of the third filter circuit F3, which is a portion of the third path r3. Of the three or more IDTs, the second IDT 20 is connected to the first common terminal side path r1p that is a portion of the first path r1 and connects the first filter circuit F1 and the common terminal Tc, the third common terminal side path r3p that is a portion of the third path r3 and connects the third filter circuit F3 and the common terminal Tc, or the second common terminal side path r2p that is a portion of the second path r2 and connects the second filter circuit F2 and the common terminal Tc.

According to this configuration, the single additional circuit A can provide the functions equivalent to those of two additional circuits to be connected to the two filter circuits F1 and F3. Because of this, it becomes possible to reduce the total number of the reflectors or the IDTs included in the additional circuit A. Further, the size of the multiplexer 1 can be reduced.

### Example 2

The first common terminal side path r1p, the third common terminal side path r3p, and the second common terminal side path r2p may be at the same potential.

According to this, it becomes possible to select a connecting destination of the second IDT 20 from a plurality of choices and increase flexibility in circuit designing of the multiplexer. Further, it becomes possible to simplify the layout of the wiring line extended from the second IDT 20. Because of this, the size of the multiplexer 1 can be reduced. The configuration of the example 2 is applicable to the example 1.

### Example 3

Each of the three or more IDTs may include a pair of the comb-shaped electrodes. The pair of comb-shaped electrodes includes one comb-shaped electrode and the other comb-shaped electrode. The one comb-shaped electrode 10a of the first IDT 10 is connected to the path connecting the first terminal T1 and the first filter circuit F1 or the path extending through the inside of the first filter circuit F1. The one comb-shaped electrode 30a of the third IDT 30 is connected to the path connecting the third terminal T3 and the third filter circuit F3 or the path extending through the inside of the third filter circuit F3. The one comb-shaped electrode 20a of the second IDT 20 is connected to the first common terminal side path r1p, the third common terminal side path r3p, or the second common terminal side path r2p. Each of the other comb-shaped electrodes 10b, 20b, and 30b of the first IDT 10, the second IDT 20, and the third IDT 30 is connected to the ground.

According to this configuration, a plurality of the one comb-shaped electrodes can be connected to respective signal paths, a plurality of the other comb-shaped electrodes can be bundled together and connected to the ground, and the layout of the wiring lines extended from the IDTs can be simplified. Because of this, the size of the multiplexer 1 can be reduced. The configuration of the example 3 is applicable to the example 1 or the example 2.

### Example 4

The second IDT 20 may be arranged between the first IDT 10 and the third IDT 30 in the first direction d1.

For example, in the case where the IDT 30 is arranged between the IDT 10 and the IDT 20, the wiring lines extended from the IDT 20 and the IDT 30 need to be crossed in a three dimensional manner to connect these wiring lines to the corresponding signal paths. However, according to the configuration described above, the wiring lines extended from the IDTs 10, 20 and 30 to the corresponding signal paths can be arranged without crossing these wiring lines. Because of this, the layout of the wiring lines can be simplified. The configuration of the example 4 is applicable to any one of the example 1 to the example 3.

### Example 5

An attenuation band outside the pass band of the first filter circuit F1, an attenuation band outside the pass band of the third filter circuit F3, and the pass band of the second filter circuit F2 may at least partially overlap with each other.

According to this, the additional circuit A connected to the first filter circuit F1 and the third filter circuit F3 can be shared, and the total number of the reflectors or the IDTs included in the additional circuit A can be reduced. Further, the decrease in insertion loss in the pass band of the second filter circuit F2 can be reduced or prevented. The configuration of the example 5 is applicable to any one of the example 1 to the example 4.

### Example 6

Each of the first filter circuit F1 and the third filter circuit F3 may be a transmission filter circuit, and the second filter circuit F2 is a reception filter circuit.

According to this, it becomes possible to ensure attenuation in the attenuation bands outside the pass bands of the transmission filters and reduce or prevent the decrease in insertion loss in the pass band of the reception filter. The configuration of the example 6 is applicable to any one of the example 1 to the example 5.

### Example 7

The reactance elements C1 and C3 may be provided in the path connecting the first filter circuit F1 and the additional circuit A and the path connecting the third filter circuit F3 and the additional circuit A, respectively.

According to this, it becomes possible to perform the adjustment of attenuation in the attenuation band easily. The configuration of the example 7 is applicable to any one of the example 1 to the example 6.

### Example 8

The three or more IDTs may include first IDT 10, the second IDT 20, and the third IDT 30.

According to this configuration, compared with the comparative example 1, the total number of the reflectors or the IDTs included in the additional circuit A can be reduced. Because of this, the size of the multiplexer 1 can be reduced. The configuration of the example 8 is applicable to any one of the example 1 to the example 7.

The multiplexers according to example embodiments of the present invention and modifications thereof have been described using examples and working examples. However, the multiplexers of example embodiments of the present invention are not limited to the foregoing examples and working examples. Other example embodiments provided by combining optional elements of the foregoing examples and working examples, working examples obtained by providing various modifications apparent to those skilled in the art to the foregoing examples without departing the scope of the present invention, and various devices each including multiplexers according to example embodiments of the present invention may also be included in the present invention.

For example, the resonators of the filter circuit of the multiplexer according to example embodiments of the present invention are, for example, surface acoustic wave resonators. However, these resonators are not limited thereto and may alternatively be acoustic wave resonators that use, for example, boundary acoustic waves.

Example embodiments of the present invention can be widely used in communication devices such as, for example, mobile phones and the like as low-loss multiplexers applicable to multiband multimode frequency standards.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multiplexer comprising:
three or more filter circuits with pass bands that are different from one another;
a common terminal, a first terminal, a second terminal, and a third terminal;
a first filter circuit in a first path connecting the first terminal and the common terminal;
a second filter circuit in a second path connecting the second terminal and the common terminal;
a third filter circuit in a third path connecting the third terminal and the common terminal; and
an additional circuit, at least a portion of which is connected in parallel to each of the first filter circuit and the third filter circuit; wherein
the additional circuit includes three or more IDTs aligned along a first direction and two reflectors on both outer sides of the three or more IDTs in the first direction;
of the three or more IDTs, a first IDT is connected to a path connecting the first terminal and the first filter circuit or a path extending through an inside of the first filter circuit, each being a portion of the first path;
of the three or more IDTs, a third IDT is connected to a path connecting the third terminal and the third filter circuit or a path extending through an inside of the third filter circuit each being a portion of the third path; and
of the three or more IDTs, a second IDT is connected to a first common terminal side path that is a portion of the first path and connects the first filter circuit and the common terminal, a third common terminal side path that is a portion of the third path and connects the third filter circuit and the common terminal, or a second common terminal side path that is a portion of the second path and connects the second filter circuit and the common terminal.

2. The multiplexer according to claim 1, wherein the first common terminal side path, the third common terminal side path, and the second common terminal side path are at a same potential.

3. The multiplexer according to claim 1, wherein
each of the three or more IDTs includes a pair of comb-shaped electrodes;
the pair of comb-shaped electrodes include one comb-shaped electrode and another comb-shaped electrode;
the one comb-shaped electrode of the first IDT is connected to the path connecting the first terminal and the first filter circuit or the path extending through the inside of the first filter circuit;
the one comb-shaped electrode of the third IDT is connected to the path connecting the third terminal and the third filter circuit or the path extending through the inside of the third filter circuit;
the one comb-shaped electrode of the second IDT is connected to the first common terminal side path, the third common terminal side path, or the second common terminal side path; and
each of the another comb-shaped electrodes of the first IDT, the second IDT, and the third IDT is connected to ground.

4. The multiplexer according to claim 1, wherein the second IDT is located between the first IDT and the third IDT in the first direction.

5. The multiplexer according to claim 1, wherein an attenuation band outside the pass band of the first filter circuit, an attenuation band outside the pass band of the third filter circuit, and the pass band of the second filter circuit at least partially overlap with one another.

6. The multiplexer according to claim 1, wherein
each of the first filter circuit and the third filter circuit is a transmission filter circuit; and
the second filter circuit is a reception filter circuit.

7. The multiplexer according to claim 1, wherein a reactance element is provided in each of a path connecting the first filter circuit and the additional circuit and a path connecting the third filter circuit and the additional circuit.

8. The multiplexer according to claim 1, wherein the three or more IDTs are three IDTs including the first IDT, the second IDT, and the third IDT.

9. The multiplexer according to claim 1, wherein the first, second, and third filter circuits are each connected to an antenna.

10. The multiplexer according to claim 1, wherein each of the first, second, and third filter circuits includes a plurality of series arm resonators connected in series with one another, and a plurality of parallel arm resonators provided in a path between a node between adjacent series arm resonators of the plurality of series arm resonators and a reference terminal.

11. The multiplexer according to claim 1, wherein each of the first, second, and third filter circuits is a ladder band pass filter.

12. The multiplexer according to claim 1, wherein a pass band of the first filter circuit is about 703 MHz to about 748 MHz.

13. The multiplexer according to claim 1, wherein a pass band of the second filter circuit is about 758 MHz to about 821 MHz.

14. The multiplexer according to claim 1, wherein a pass band of the third filter circuit is about 832 MHz to about 862 MHz.

15. The multiplexer according to claim 1, wherein the three or more IDTs are four IDTs including the first IDT, the second IDT, the third IDT, and a fourth IDT.

16. The multiplexer according to claim 1, wherein the three or more IDTs are five IDTs including the first IDT, the second IDT, the third IDT, a fourth IDT, and a fifth IDT.
